(19) United States
(12) Patent Application Publication
(10) Pub. No.: US 2014/0060644 A1
(43) Pub. Date: Mar. 6, 2014

(54) 2D CRYSTALLINE FILM BASED ON ZNO INTEGRATION OF ONTO A CONDUCTIVE PLASTIC SUBSTRATE

(71) Applicant: Commissariat A L'Energie Atomique Et Aux Energies Alternatives, Paris (FR)

(72) Inventors: Solenn BERSON, Chambery (FR); Stéphane GUILLEREZ, Lepin Le Lac (FR); Valentina IVANOVA-HRISTOVA, Grenoble (FR); Sylvia SANCHEZ, Vaulnaveys Le Haut (FR)

(73) Assignee: Commissariat A L'Energie Atomique Et Aux Energies Alternatives, Paris (FR)

(21) Appl. No.: 14/041,163

(22) Filed: Sep. 30, 2013

Related U.S. Application Data
(63) Continuation of application No. PCT/FR2012/050600, filed on Mar. 22, 2012.

(30) Foreign Application Priority Data
Apr. 19, 2011 (FR) 11.53398

(51) Int. Cl. H01L 51/44; H01L 51/00

(52) U.S. Cl. CPC H01L 51/442; H01L 51/0006
USPC 136/256; 438/82

(57) ABSTRACT

The invention relates to a method for forming, on a conductive plastic substrate, a 2D crystalline layer based on zinc oxide, possibly doped, characterized in that: the 2D layer is formed by electrochemical deposition; the electrochemical deposition is performed at a temperature ranging between 55° C. and 65° C.; the electrochemical deposition is performed in the presence of oxygen, by means of a solution including a zinc source at a concentration ranging between 2.5 mM and 7 mM; and a supporting electrolyte at a concentration ranging between 0.06 M et 0.4 M.

### BACKGROUND OF THE INVENTION

1. Technical Field

The present invention falls within the search for architectures and films constitutive of photovoltaic devices enabling to improve the efficiencies and the stability of current devices.

More specifically, the invention relates to the electrochemical deposition of transparent semiconductor oxide (n and p), and in particular of zinc oxide (ZnO), on a plastic substrate covered with a conductive material.

This deposition may be integrated in an optoelectronic device such as an organic light-emitting diode (OLED), a flexible polymer light-emitting diode (PLED), a flexible photovoltaic device (PV), or a flexible organic photodetector (OPD).

2. Description of the Related Art

Organic photovoltaic cells (PV) are devices capable of converting solar energy into electric energy by means of the use of semiconductor materials, to produce a photovoltaic effect. Active materials, as well as the architectures of such devices, are still evolving to meet performance and lifetime criteria enabling to widen the field of application of these technologies.

As a reminder, the conventional and inverse structures of organic PV cells are schematically shown in FIG. 1A and in FIG. 1B, respectively. Conventionally, a substrate 1 is covered with the following successive layers:

a conductive layer 2 used as a first electrode;

a p semiconductor layer 3;

an active layer 4;

an n semiconductor layer 5; and

a conductive layer 6 behaving as a second electrode.

In an inverse structure, the stack has the following sequence:

substrate 1;

a conductive layer 6 used as a first electrode;

an n semiconductor layer 5;

an active layer 4;

a p semiconductor layer 3;

a conductive layer 2 used as a second electrode.

The use of metal oxides as semiconductors 3, 5 to be used as an interface between active layer 4 and electrode 2, 6 is well known. In particular, zinc oxide (ZnO) is known for its use as an n layer (5).

Thus, for photovoltaic applications, document Hames et al. (Solar Energy 84 (2010) 426-43) describes the deposition of ZnO wires electrochemically formed on a 2D ZnO film, on a glass substrate covered with an ITO layer. After anneals at 100° C. for the 2D film, and then at 200° C. for the 2D+3D film, conversion efficiencies of 2.44% are reported. More specifically, this document describes different structures based on ZnO formed on a conductive glass substrate: a 2D film, ZnO wires forming a 3D structure, or a combination thereof, that is, ZnO wires formed on a 2D ZnO film. Such a combination appears as the most promising, with a conversion efficiency of 2.44%. Obtaining these structures however requires a final anneal at 200° C. for the complete structure.

However, and in the context of PV cells, no prior document has described the electrochemical forming of 2D ZnO films or of 3D structures on plastic substrates. Now, this type of substrates has a promising future.

Further, in a more general context, the integration of electrochemically-prepared planar (2D) crystalline ZnO films has never been reported. Only the obtaining of sheets of ZnO wires (and thus of 3D ZnO structures) has been described in relation with the electrochemical deposition technique.

The present invention thus falls within the search for technical solutions enabling to form 2D structures, for example, made of ZNO, on plastic substrates, especially in order to integrate them in photovoltaic devices.

### SUMMARY OF THE INVENTION

The present invention provides, for the first time, means for forming a 2D ZnO-based crystalline structure on a conductive plastic substrate. The method according to the invention implements the electrochemical deposition technique, which has the advantage of being relatively simple and inexpensive.

Of course, document Hames et al., had already reported the possibility of using such a deposition technique to obtain a 2D ZnO film on a glass substrate covered with a conductive layer. However, the need for an anneal at high temperature (at least 100° C.), for a technique besides providing unsatisfactory results (1.64% conversion efficiency), would have deterred those skilled in the art from implementing this technique to perform depositions of 2D films of metal oxides on plastic substrates which deteriorate under the action of heat.

Unlike prior art, the method according to the invention thus is characterized by the absence of any anneal step, which anneal is generally performed at a temperature greater than or equal to 100° C., or even 200° C. In other words, the method is carried out at low temperature, advantageously below 100° C.

More specifically, the present invention relates to a method for forming, on a conductive plastic substrate, a 2D crystalline film based on zinc oxide (ZnO), possibly doped, according to which:
the 2D film is formed by electrochemical deposition;
the electrochemical deposition is carried out at a temperature ranging between 55° C. and 65° C.;
the electrochemical deposition is performed in the presence of oxygen, by means of a solution comprising a zinc source at a concentration ranging between 2.5 mM and 7 mM, and a supporting electrolyte at a concentration ranging between 0.06 M et 0.4 M.

In the context of the invention, a 2D layer designates a continuous layer at the surface of the substrate.

Preferably, the method according to the invention enables to obtain a 2D crystalline layer which is both different from a 2D amorphous layer and from 3D structures, especially nanowires.

In the case of ZnO, its crystalline form is characterized by the presence, detectable by X-ray diffraction, of at least one of the two peaks, (002) and (101), advantageously the 2. Preferably, the intensity of the (002) peak, and possibly that of the (101) peak, is greater than or equal to 1.2, or even to 1.5 times that of the background noise.

Further, and advantageously, to better distinguish a 2D crystalline film according to the invention from 3D structures, the ratio of the intensities of the (002) peak and of the (101) peak, (I(002)/I(101)), is smaller than or equal to 3.5, advantageously smaller than or equal to 3.

Further, and advantageously, the 2D crystal layer obtained in the context of the invention has a surface roughness, measured by 2×2 μm² AFM, smaller than or equal to 15 nm, and advantageously smaller than or equal to 10 nm.

According to another feature, this layer advantageously has a uniform thickness, for example, with variations not exceeding 10% of the thickness, and thus forms a planar homogeneous layer. In the context of the invention, the thickness of the layer advantageously ranges between 15 nanometers and 400 nanometers. In other words, the 2D layer obtained by means of the method according to the invention is characterized by the absence, in particular, of nanoparticles, of nanoballs, of nanorods, or nanowires, characteristic of 3D structures.

Further, the small thickness of the obtained 2D layers, due to a low deposition charge, translates as a conduction and stability increase.

More advantageously still, the 2D layer formed in the context of the invention is transparent for the solar spectrum, with a transmittance advantageously greater than 80%. This quality is due to the small thickness of the layer and to its homogeneity and thus results from the method implemented in the context of the present invention.

As mentioned, the 2D layer contains metal oxide, or is even only made of pure or mixed metal oxide. Further, this layer advantageously contains crystalline metal oxide. It is here spoken of a crystalline material when the full width at half-maximum (FWHM) of the diffraction peak is smaller than 3.

Advantageously, and especially for the photovoltaic application, the metal oxide used in the context of the invention is a semiconductor, more advantageously still of zinc oxide (ZnO). However, other metal oxides also having semiconductor properties may be used. It may be a TMOSC (Transparent Metal Oxide SemiConductor) of type p or n. It for example is a metal oxide selected from the following group: nickel oxide (NiO) (p), copper oxide (CuO) (p), Cu₂O (p), or SnO₂ (n).

Further, the metal oxide used may be conductive, and not only a semiconductor. Such is for example the case for doped semiconductor metal oxides, such as aluminum-doped zinc oxide (Al-doped ZnO or AZO).

Advantageously, the invention thus aims at a method for forming a crystalline 2D layer based on zinc oxide (ZnO), possibly doped. According to a preferred embodiment, the 2D layer is formed of ZnO, possibly doped, for example with aluminum.

According to the invention, the substrate having the deposition performed thereon is a plastic substrate, for example, PET (polyethylene terephtalate), PEN (polyethylene naphtalate) or polycarbonates. Certain substrates used in the context of the invention (especially made of PET and PEN) are further flexible.

According to the invention, the substrate is also conductive. In particular, in the context of photovoltaic devices, the substrate is covered with a conductive layer used as an electrode, advantageously formed by means of a TCO (“Transparent Conductive Oxide”), for example, ITO (for “Indium Tin Oxide” or “tin-doped indium oxide”), GZO (“Gallium-doped Zinc Oxide”), AZO (based on aluminum), YZO (based on Yttrium), IZO (based on indium), or FTO (SnO₂:F).

As illustrated in FIGS. 2A and 2B, the ITO conductive layer, obtained on a PET substrate (FIG. 2B), is rougher, not as well crystallized than on glass (FIG. 2A). In spite of this, the deposition of the metal oxide by means of the method according to the invention provides a planar, homogeneous, and crystalline 2D layer, and this even in the absence of any anneal.

The electrochemical deposition according to the invention is advantageously performed in a conventional electrolytic bath, with a standard O₂ source.

More generally, the electrochemical deposition is advantageously performed in the presence of oxygen, for example, with electrolytes saturated with molecular oxygen or in the presence of oxygenated water (H₂O₂).

Further, and as already mentioned, the electrochemical deposition is advantageously performed at a temperature lower than 100° C. It should be noted that the deposition temperature may be controlled by the control of the temperature of the electrolytic bath.

Thus, for a ZnO deposition, the temperature advantageously ranges between 50° C. and 85° C., preferentially ranges between 55° C. and 65° C., and is more advantageously still equal to 60° C.

Conventionally, the electrochemical deposition is carried out by means of a solution, advantageously aqueous, comprising the electrolytes.

In the context of the invention, said solution advantageously comprises:
a source of zinc, in particular of Zn²⁺ ions;
a supporting electrolyte, advantageously adapted to the zinc source in presence.

Among zinc sources capable of being used, the following can be mentioned: zinc chloride (ZnCl₂), zinc sulphate (ZnSO₄), zinc acetate (Zn(CH3COO)₂), zinc perchlorate (Zn(ClO₄)₂).

Among supporting electrolytes, the following can be mentioned: potassium, sodium, or lithium chloride (KCl, NaCl, LiCl), potassium or sodium sulphate (K₂SO₄, Na₂SO₄), potassium, sodium, or lithium acetate (CH₃COOK, CH₃COONa, CH₃COOLi), lithium, potassium, or sodium perchlorate (LiCLO₄, KClO₄, NaClO₄).

“Supporting electrolyte adapted to the zinc source in presence” designates the fact that the supporting electrolyte brings the same chemical species as the zinc source in presence. As an example, potassium, sodium, or lithium chloride will be selected if the zinc is brought in the form of zinc chloride.

It has further been shown in the context of the present invention that the respective concentrations of the zinc source and of the supporting electrolyte are important to obtain the 2D crystalline layer:

Thus, the concentration of the zinc source advantageously ranges between 2.5 mM and 7 mM, and more advantageously still ranges between 4 and 6 mM. More specifically, the zinc source is at a concentration such that the Zn²⁺ concentration in the solution ranges between 2.5 mM and 7 mM, and more advantageously still between 4 and 6 mM.

Further, the supporting electrolyte concentration advantageously ranges between 0.06 M and 0.4 M, more advantageously still between 0.07 M and 0.2 M.

The ZnO deposition is further advantageously performed at small charge, between 0.05 and 0.4 C/cm², preferably between 0.1 and 0.2 C/cm².

As already mentioned, the targeted method is particularly advantageous in photovoltaics.

Thus, and according to another aspect, the present invention relates to a method for manufacturing an organic photovoltaic device on a conductive plastic substrate, according to which the semiconductor (p or n) is deposited by means of the above-described method. Mainly, the deposition of the semiconductor (p or n) used as an interface between the active layer and the electrode is an electrodeposition and the forming of this semiconductor layer requires no anneal.

According to a specific embodiment, it is a method for manufacturing an organic photovoltaic cell on plastic covered with a TCO layer, according to which the deposition of the semiconductor (p or n), advantageously ZnO, is performed by electrochemical deposition, in the above-described conditions.

Further, the present invention provides, for the first time and due to the method described hereabove, an organic photovoltaic device comprising a conductive plastic substrate covered with a 2D crystalline layer based on ZnO, possibly doped.

Such a layer, for example, made of ZnO, appears to be of very good crystal quality, and is relatively planar, homogeneous, or even transparent. This results in good dielectric qualities and a good resistance to aging.

In particular, and as already mentioned, a 2D crystalline layer according to the invention is advantageously characterized by:
a ratio between the intensities of the (002) peak and of the (101) peak (I(002)/I(101)) smaller than or equal to 3.5, advantageously smaller than or equal to 3; and/or
a surface roughness, measured by 2×2 μm² AFM, smaller than or equal to 15 nanometers, advantageously smaller than or equal to 10 nanometers.

The advantages of the present invention will better appear from the following embodiments.

### BRIEF DESCRIPTION OF THE DRAWINGS

FIGS. 1A and 1B show diagrams of the conventional and inverse structures of organic PV cells.

FIGS. 2A and 2B show images obtained in scanning electron microscopy (SEM) of a glass substrate covered with an ITO layer and of a PET substrate covered with an ITO layer.

FIG. 3 shows a diagram of an electrochemical cell enabling to implement the method according to the invention.

FIGS. 4A-4D show images obtained by scanning electron microscopy (SEM) of ZnO layers electrochemically obtained on a conductive plastic substrate at different charge rates and different temperatures:

FIG. 4A: PET/ITO substrate; 60° C. and 0.2 C/cm²;

FIG. 4B: PET/ITO substrate; 60° C. and 0.1 C/cm²;

FIG. 4C: PET/ITO substrate; 60° C. and 0.6 C/cm²; and

FIG. 4D: PEN/GZO substrate; 60° C. and 0.1 C/cm².

FIGS. 5A-5C show images obtained by scanning electron microscopy (SEM) of ZnO layers electrochemically obtained on a conductive glass substrate at 70° C. and at different charge rates:

FIG. 5A: 0.2 C/cm²;

FIG. 5B: 0.4 C/cm²; and

FIG. 5C: 0.6 C/cm².

FIG. 6 shows an XRD (X-ray diffraction) spectrum of a ZnO layer obtained at 60° C. with an electrolyte of 5.10⁻³ M ZnCl₂ and 0.1 M KO at a potential of −1.0 vs SCE, deposited on a PET substrate covered with ITO.

FIG. 7 compares the XRD (X-ray diffraction) spectrum of a 2D crystalline ZnO layer obtained by means of the method according to the invention with ZnO nanotubes or amorphous ZnO layers.

FIGS. 8A and 8B illustrate the difference in roughness between a 2D ZnO layer obtained by means of the method according to the invention and a 3D layer of nanowires (2×2 μm² AFM).

FIGS. 9A-9C show images obtained by scanning electron microscopy (SEM) of ZnO layers obtained at different supporting electrolyte concentrations:

FIG. 9A: 5 mM ZnCl₂+0.05 M KCl;

FIG. 9B: 5 mM ZnCl₂+0.1 M KCl; and

FIG. 9C: 5 mM ZnCl₂+0.5 M KCl.

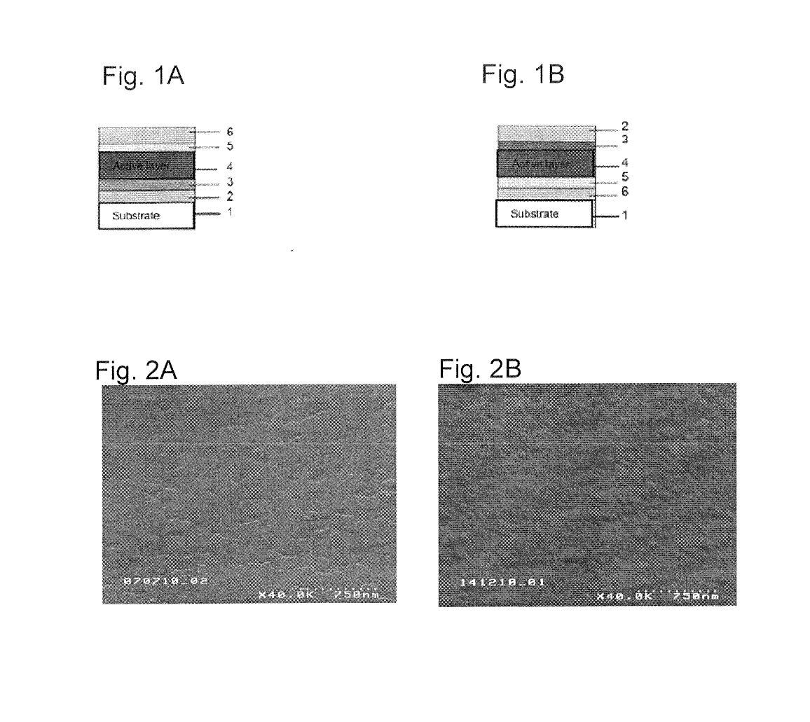

### EXAMPLES OF EMBODIMENT

The following non-limiting embodiments, in relation with the accompanying drawings, aim at illustrating the invention. The present invention will be further illustrated in relation with zinc oxide (ZnO).

### 1/Electrodeposition of the ZnO Layer:

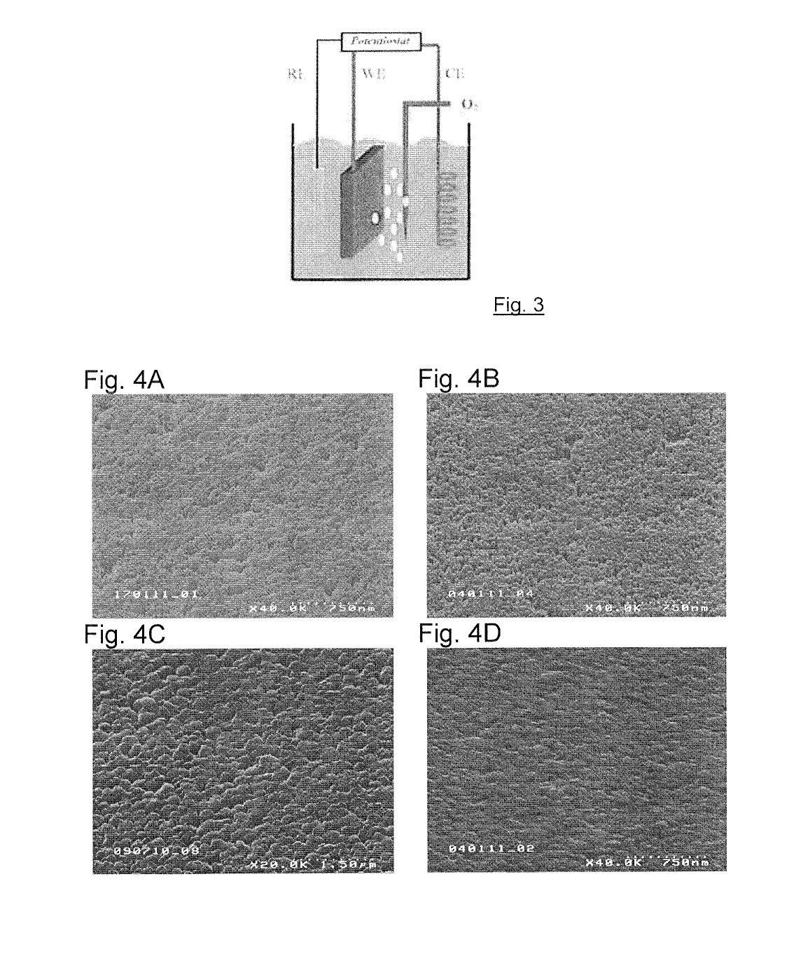

The electrodeposition of ZnO is performed in a standard electrochemical cell with three electrodes, where a Pt wire is used as a counter-electrode and a saturated calomel electrode (SCE) is used as a reference electrode (FIG. 3).

The work electrode is a PET plastic substrate, covered with a conductive and transparent oxide In₂O₃ and SnO₂ (ITO), with a resistance per square of approximately 15Ω_{square}. The active surface area is set to 1.7 cm².

The 2D ZnO layers are electrodeposited at a constant potential of −1 V vs SCE, from an aqueous solution containing 5 mM of ZnCl₂ and 0.1 M of KCl. The potential is controlled by a PARSTAT 2273 (Princeton Applied Research) potentiostat/galvanostat.

All experiments are carried out with electrolytes saturated with molecular oxygen.

The temperature of the bath may vary between 50° C. and 85° C. The charge density may also vary between 0.05 C.cm⁻² and 0.8 C.cm⁻². The charge density is used to control the film thickness.

2/Analysis of the ZnO layers:

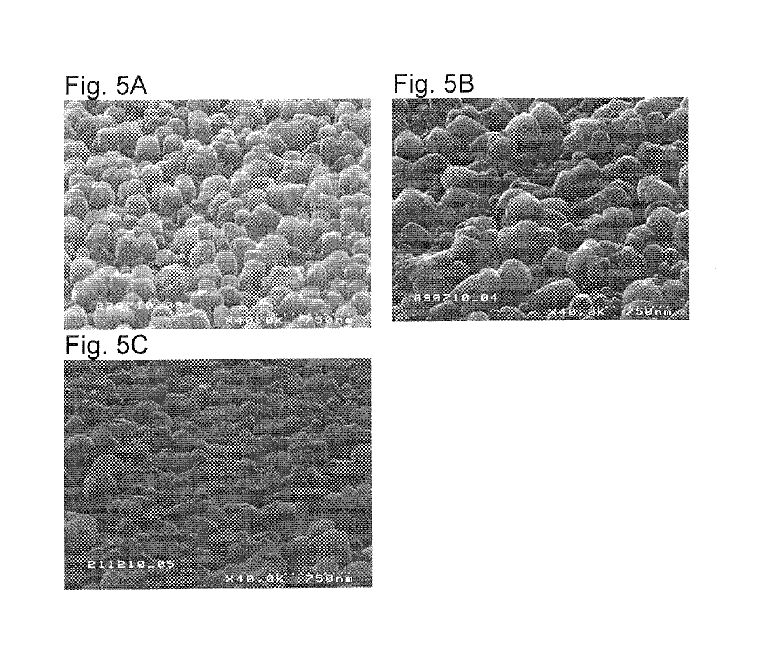

The morphology of the layers is studied by means of a S-4100 scanning electronic microscope (FIGS. 4A-4D). The crystalline structure is analyzed by an X-ray brucker D5000 diffractometer, by using the K_{α1} radiation of copper (γ=1.5406 μm) in θ-2θ mode.

FIGS. 4A-4D show 2D layers obtained at 60° C. and for low deposited charges (0.1 or 0.2 C.cm²).

As a comparison, in FIGS. 5A-5C at the same scale, which corresponds to a conductive glass substrate, it is necessary to rise up to 70° C. and the obtained structure do not correspond to 2D layers as understood in the disclosure, that is, planar and homogeneous.

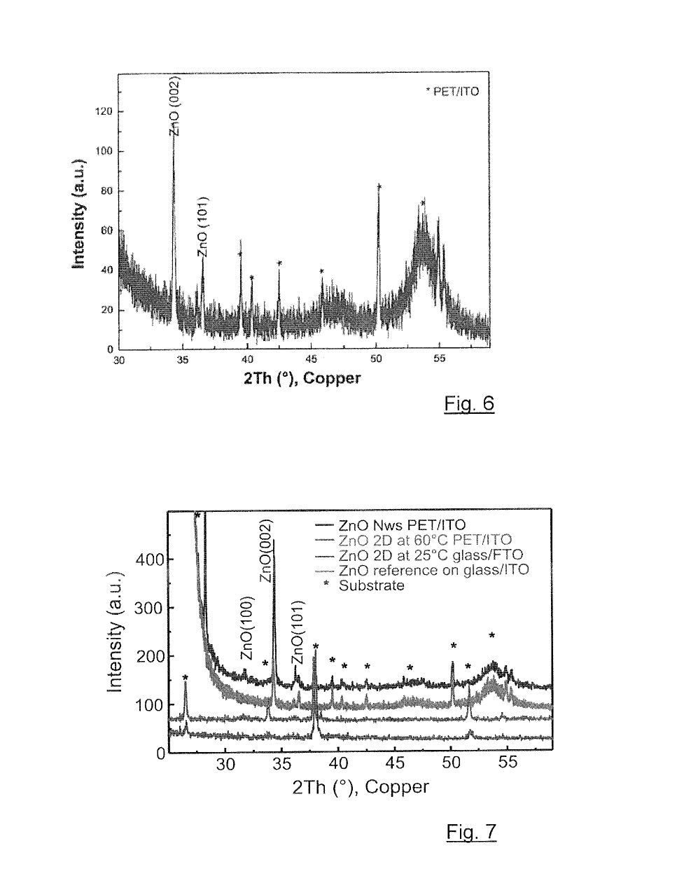

The (002) and (101) peaks of FIG. 6 show that the film deposited at 60° C. on a plastic substrate actually is crystalline ZnO. Table 1 hereafter lists the diffraction peaks corresponding to the signature of crystalline ZnO:

TABLE 1

| peak | 2θ (°) | FWHM (°) |
|---|---|---|
| ZnO (002) | 34.325 | 0.175 |
| ZnO (101) | 36.588 | 0.120 |

FIG. 7 compares the XRD (X-ray diffraction) spectrum of a 2D crystalline ZnO layer obtained by means of the method according to the invention with ZnO nanotubes or amorphous ZnO layers. More specifically, the following can be observed:
XRD of ZnO nanowires (3D): very strong (002) orientation, along axis c;
XRD of a 2D ZnO layer obtained by means of the method according to the invention (T=60° C.): crystallized;
XRD of a 2D ZnO layer at 25° C.: amorphous;
XRD of a ZnO reference: amorphous.

It can be observed that the intensity of the (002) peak of the ZnO is 3 times greater for nanowires (ZnO NWs) than for the 2D layer electrodeposited at 60° C. The ratio between the (002) peak and the (101) peak is I(002)/I(101)=6.5 for nanowires and 2.9 for 2D layers, that is, a ratio which is 2.2 times greater for nanowires. The width at mid-height of the (002) peak is 0.147 for ZnO nanowires is 0.175 for 2D ZnO layers. Further, the layers prepared at a temperature lower than 50° C. are amorphous (see, in the drawing, the layer at 25° C.). The reference layer, used in current technology and prepared by sol-gel process, is also amorphous.

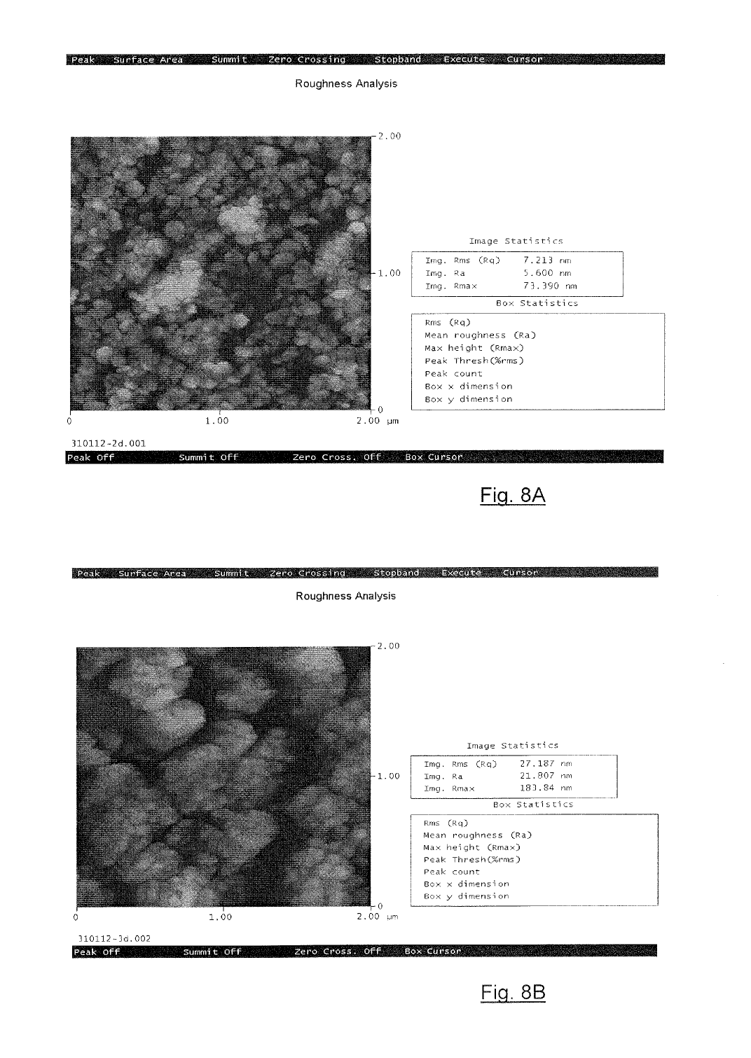

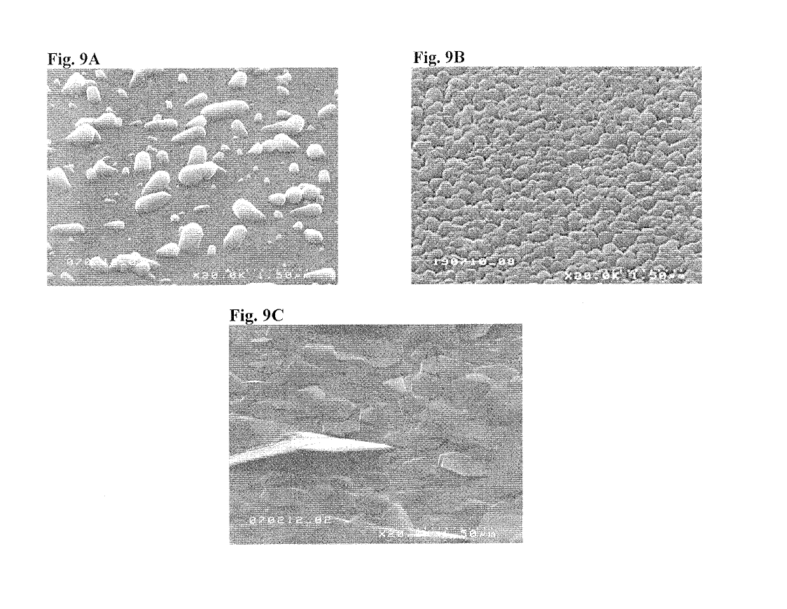

FIGS. 8A and B illustrate the difference in roughness between a 2D ZnO layer obtained by means of the method according to the invention and a 3D layer of nanowires (2×2 μm² AFM):

RMS 2D layer: 7.2 nm;

RMS 3D layer: 27.2 nm.

In this specific case, there exists a 3.8 roughness factor between the 2D and 3D layers, respectively.

Further, the impact of the supporting electrolyte concentration, in the case in point, KCl, at a constant ZnCl₂ concentration (=5 mM), has been highlighted:

for 0.05 M of KCl: no continuous ZnO layer (FIG. 9A);

for 0.1 M of KCl: conformal 2D ZnO layer (FIG. 9B); and

for 0.5 M of KCl: no forming of ZnO (FIG. 9C).

### 3/Integration of the ZnO Deposits in a Photovoltaic Device:

Such electrochemical ZnO deposits on a conductive plastic or conductive glass substrate have been integrated in organic photovoltaic devices. The results obtained in photovoltaic cells appear in the following table:

| | | Charge | ZnO | Voc | Jsc | | |
|---|---|---|---|---|---|---|---|
| Substrate | T° C. | C · cm² | quality | mV | mA · cm⁻² | FF % | PCE % |
| PET/ITO | 60 | 0.1 | Homogeneous 2D | 572 | 9.7 | 51.9 | 2.91 |
| PET/ITO | 60 | 0.2 | Homogeneous 2D | 568 | 9.3 | 54.5 | 3.29 |
| PET/ITO | 60 | 0.4 | Homogeneous 2D | 565 | 8.6 | 51.1 | 2.61 |
| Glass/ITO | 70 | 0.2 | Non homogeneous | 538 | 9.7 | 43.2 | 2.25 |
| | | | 3D | | | | |
| Glass/ITO | 70 | 0.4 | Non homogeneous | 546 | 10.1 | 44.4 | 2.47 |
| | | | 3D | | | | |

Voc: open-circuit voltage
Jsc: current density in short-circuit
FF: Fill Factor
PCE (%): Power Conversion Efficiency.

In optimized conditions, the obtained conversion efficiencies are 3.29% on PET/ITO, which prove the quality of the ZnO layer, to be compared with the 3.3% spin coating reference.

In the same conditions on glass/ITO, it has not been possible to obtain a homogeneous 2D layer: a certain increase of the homogeneity has been observed by increasing its temperature and deposited charge but without reaching the structure of a 2D layer. Even at higher temperature and with more deposited material, the results are not as good on glass/ITO than on PET/ITO.

In literature, better efficiencies are obtained at 3.9% for the glass/ITO/ZnO nanowire system, where the thin ZnO layer is formed by wet process with anneals at 500° C. No result on plastic substrate is reported.

1. A method for forming, on a conductive plastic substrate, a 2D crystalline layer based on zinc oxide (ZnO), possibly doped, according to which:
the 2D layer is formed by electrochemical deposition;
the electrochemical deposition is performed at a temperature ranging between 55° C. and 65° C.;
the electrochemical deposition is performed in the presence of oxygen, by means of a solution comprising:
a zinc source at a concentration ranging between 2.5 mM and 7 mM; and
a supporting electrolyte at a concentration ranging between 0.06 M and 0.4 M.

2. The method for forming a 2D crystalline layer of claim 1, wherein the conductive plastic substrate is a plastic substrate covered with a TCO layer.

3. The method for forming a 2D crystalline layer of claim 1, wherein the deposition is performed at a temperature equal to 60° C.

4. The method for forming a 2D crystalline layer of claim 1, wherein the zinc source is selected from the following group: zinc chloride (ZnCl₂), zinc sulphate (ZnSO₄), zinc acetate (Zn(CH3COO)₂), zinc perchlorate (Zn(ClO₄)₂).

5. The method for forming a 2D crystalline layer of claim 1, wherein the zinc source is at a concentration ranging between 4 and 6 mM.

6. The method for forming a 2D crystalline layer of of claim 1, wherein the supporting electrolyte is selected from the following group: potassium, sodium, or lithium chloride (KCl, NaCl, LiCl), potassium or sodium sulphate (K₂SO₄, Na₂SO₄), potassium, sodium, or lithium acetate (CH₃COOK, CH₃COONa, CH₃COOLi), lithium, potassium, or sodium perchlorate (LiClO₄, KClO₄, NaClO₄).

7. The method for forming a 2D crystalline layer of claim 1, wherein the supporting electrolyte is at a concentration ranging between 0.07 M and 0.2 M.

8. The method for forming a 2D crystalline layer of claim 1, wherein the electrochemical deposition is performed with an electrolyte saturated with molecular oxygen or in the presence of oxygenated water.

9. The method for forming a 2D crystalline layer of claim 1, wherein the deposition is performed with a charge ranging between 0.05 and 0.4 C/cm², preferably ranging between 0.1 and 0.2 C/cm².

10. A method for manufacturing a photovoltaic organic device on a conductive plastic substrate, according to which the (p or n) semiconductor is deposited by means of the method of claim 1.

11. An organic photovoltaic device comprises a conductive plastic substrate covered with a 2D crystalline layer based on zinc oxide (ZnO), possibly doped, capable of being formed by means of the method of claim 1.

12. The organic photovoltaic device of claim 11, wherein the layer has:
a ratio between the intensities of the (002) peak and of the (101) peak (I(002)/I(101)) smaller than or equal to 3.5, advantageously smaller than or equal to 3; and/or
a surface roughness, measured by 2×2 μm² AFM, smaller than or equal to 15 nm, advantageously smaller than or equal to 10 nanometers.

13. The organic photovoltaic device of claim 11, wherein the layer is transparent.
